(19) United States
(12) Patent Application Publication
(10) Pub. No.: US 2011/0140265 A1
(43) Pub. Date: Jun. 16, 2011

(54) Packaging of Silicon Wafers and Mating Pieces

(76) Inventor: George Dennis Scheber, Sheldon, IL (US)

(21) Appl. No.: 12/635,562

(22) Filed: Dec. 10, 2009

(51) Int. Cl. H01L 23/498

(52) U.S. Cl. 257/697; 257/693; 257/E23.068

(57) ABSTRACT

By creating a package (MVLC) that has a redundant set of pins, twice as many points of contact are generated. More contacts create more routing and component placement options.

Incorporating slots on the underside of the MVLC will promote radiation under the MVLC.

By creating a mating piece (a Saddle) discrete components can be moved to a more desirable area of the main printed circuit board or placed in and on the Saddle itself.

A Saddle may or may not require a flex circuit.

A Saddle could be no more than a flex circuit.

Positioning capacitors in particular on the Saddle makes a supply current become more effective, which improves performance.

All of the Saddle layers are designed to enhance performance and/or reduce the member of discrete components required on the main printed circuit board near the MVLC.

In general, creating more usable room on the main printed circuit board promotes a better design and invites circuit expansion.

### BACKGROUND OF THE INVENTION

The most critical component, via, and trace areas of many high density printed circuit boards is at the site of the Central Processing Unit (CPU). This occurs because the CPU requires large numbers of discrete components to be placed in its proximity to function correctly. If a method is devised to allow some of the many components to be moved away from the CPU, or be replaced by a device that clears some space near the CPU, printed circuit board design will be enhanced. Such enhancement will lower design cost. It will also encourage more circuitry and function without enlarging the size and shape of the printed circuit board.

### BRIEF SUMMARY OF THE INVENTION

This new packaging consists of a two piece assembly which will allow many discrete components to be replaced or moved away from a CPU without compromising the design or function of the circuit or product. It will also promote radiation under the CPU.

### DETAILED DESCRIPTION OF THE INVENTION

### General Specification of Piece One (MVLC)

Hereafter a chip with a large number of pins is referred to as a VLC. Once repackaged with the addition of top side contacts it is referred to as a MVLC.

A Central Processing Unit (CPU) is considered a VLC. A CPU requires large numbers of discrete components to function correctly. Hundreds of such discrete components crowd the area surrounding a CPU as their proximity is a requirement for proper function.

Decreasing the number of discrete components required near a VLC on the printed circuit board, in order to free up space near the VLC can be accomplished using VLC repackaging as described below.

VLC packages with a surface pin (Through Pin, Ball Grid Array pin,—as well as any other pin) will be manufactured to have connection points on the top surface of the package mirroring the conventional connection points on the bottom surface of the same package. Such dual pinned packages shall be referred to as a MVLC.

Mirrored pin patterns may be similar in nature to the original package pins patterns in number and shape.

A variance could occur, when an unused VLC pin is omitted in the mirrored pattern if it isn't electrically necessary.

Likewise some clusters of common pins (Powers and Grounds for instance) may be reduced in number in order to free up surface area on the mirrored pattern.

Other pattern changes for such things as alignment pins, mounting holes, and to provide attachment areas for socket usage may occur.

MVLC top pins may differ from bottom pins. For example Through Pin package bottoms may have a Ball Grid Array pattern on top. Likewise a Ball Grid Array pattern on the bottom may have Through Pin connections on the top. This pin type versatility applies to all package pin types.

MVLC package bottoms have a series of slots which begin at the inner edge of the pin pattern and radiate along the x and y axis to the perimeter of the package on a taper. This facilitates heat and gas dissipation outward after assembly.

Remaining channels, between rows and columns of pins, contains additional tapered slots along the x and y axis extending to the package edge.

Decreasing the number of discrete components required near a VLC on the printed circuit board in order to free up space near the VLC, can be accomplished using a MVLC plus a mating piece (Piece Two) fastened to the top of the MVLC.

### General Specification of Piece Two (Saddle)

Piece two, the mating piece, will be referred to as a Saddle.

A Saddle is a small printed circuit board.

A Saddle has bottom side contacts that mate with top side MVLC contacts to establish electrical conductivity between the two pieces when joined.

A Saddle is often larger than (and thus overhangs the sides of) its mating MVLC.

A Saddle may have components mounted on it's top side.

A saddle may have components mounted on it's bottom side.

A Saddle may have connectors mounted on any edge.

A Saddle may incorporate edge connectors within itself.

Omit [0023].

Saddles may have delay and/or differential pair lines.

A Saddle may incorporate capacitance within its own layers.

A Saddle may incorporate resistance within its own layers.

A Saddle may incorporate filters within its own layers.

A Saddle may incorporate termination within its own layers.

A Saddle may incorporate any combination of capacitance, resistance, termination, and filters within its own layers and substrates.

Usage

A Saddle may be directly attached to the MVLC using conventional methods.

A Saddle may be attached to a MVLC as a sub-assembly and be pre-tested as such.

Sub-assemblies may include a MVLC, a Saddle, one or more flex circuits, one or more small printed circuit boards at the far end of the flex circuit(s), or any combination of components.

An advantage other than obtaining space near a VLC include enhancing the performance of the VLC by promoting proper termination of signals.

An advantage other than obtaining space near a VLC include enhancing the performance of the VLC by promoting wafer decoupling.

Obtaining space near a VLC will afford space for other discrete components (thus enhancing printed board function and design)

Signal transmission lines can be taken to a more favorable area on the printed circuit board by fastening one end of a flex circuit to a Saddle and the other end to the main printed circuit board or to an independent circuit card.

Terminating components can be added on the printed circuit board at the far end of the flex circuit, which can be located in a less congested area on the printed circuit board.

Specification for Partial Saddle Contacts.

A Saddle can be made with a contact pattern that only accommodates a specific purpose or one type of function.

A specific purpose may be for capacitors for MVLC decoupling.

A specific purpose may be for resistor/capacitor (RC) networks.

A purpose may be for any specialized or combination of discrete component MVLC needs.

Specification for Saddle Shapes and Sizes

Saddle shapes have an open area immediately above the MVLC silicon wafer to allow heat and vapor dissipation.

A Saddle may have mounting holes (A MVLC may have mounting holes)

A Saddle may have alignment pins (A MVLC may have alignment pins)

A Saddle may have socket related surfaces (A MVLC may have socket related surfaces)

A Saddle may have a pin pattern to accommodate a subset of specific chip requirements. Two such subsets are called C-Saddles and P-Saddles.

Specification for C-Saddle Contact Pins

A C-saddle is circuit centric.

C-Saddle pins may be any set of related and/or unrelated signal pins, and/or ground pins, and/or voltage pins, to the exclusion of all other pins.

C-Saddle groups of pins are chosen for particular circuit pin needs to the exclusion of all other circuit pin needs.

Specification for P-Saddle Contact Pins

Rather than signal centric, a P-Saddle is position centric.

A P-Saddle reflects pin positions on a MVLC rather than circuit particulars.

Concentric rows and columns of pins are referred to as “banks”.

P-Saddle pin positions can be exterior perimeter banks of pins.

P-Saddle pin positions can be interior perimeter banks of pins.

P-Saddle pin positions can combine any combination of exterior and interior perimeter banks of pins.

P-Saddle pin positions can combine any combination of exterior and interior perimeter rows and/or columns of pins.

1. A MVLC is an integrated circuit package which, while keeping the usual set of contacts on the bottom surface of the package, has a set of contacts on the top surface of the package which mirror the contacts found on the bottom surface of the package, thus creating a package with two sets of contacts.

2. There is continuity, contact per contact, between each contact on the MVLC package top with its complimentary contact on the package bottom.

3. The pattern of the bottom contacts on a MVLC is similar to the pattern of contacts on the top of the MVLC except when some contacts on the top of the package have been offset to accommodate other features.

4. Pin types (contacts) may be the same on both sides of a MVLC.

5. Pin types may differ from side to side on a MVLC (MVLC bottom side contacts may differ from top side contacts in physical size and shape.

6. Any combination of sets of contact points on a MVLV may exist, for instance, one side of a MVLC may have Leaded Through Pins and the mirrored side of the MVLC may have Ball Grid Array contact pins.

7. MVLC packages may have slots (some of which are tapered) on the bottom side which will promote radiation from under the MVLC.

8. The MVLC mating piece (a Saddle) is a populated (contains components) printed circuit board whose bottom surface contacts mate with the top surface contacts of a MVLC.

9. When a MVLC only requires a flex circuit (one end of the flex circuit mounts directly to the MVLC) the flex circuit is the Saddle.

10. A Saddle has a centrally located open area (hole in the printed circuit board) above its mating MVLC to allow vapor and heat dissipation from the MVLC.
